(19) United States
(12) Patent Application Publication
(10) Pub. No.: US 2026/0018404 A1
(43) Pub. Date: Jan. 15, 2026

(54) METHOD FOR FORMING AN ULTRAVIOLET RADIATION RESPONSIVE METAL OXIDE-CONTAINING FILM

(71) Applicant: ASM IP Holding B.V., Almere (NL)

(72) Inventors: Hannu Huotari, Espoo (FI); Jan Willem Maes, Wilrijk (BE)

(21) Appl. No.: 19/327,367

(22) Filed: Sep. 12, 2025

Related U.S. Application Data
(63) Continuation of application No. 17/545,047, filed on Dec. 8, 2021, now Pat. No. 12,444,599.
Application No. 17/545,047 is a division of application No. 16/206,589, filed on Nov. 30, 2018, now Pat. No. 11,217,444.

(51) Int. Cl. H01L 21/02; C23C 16/40; C23C 16/455; C23C 16/56; H01L 21/033; H01L 21/3213

(52) U.S. Cl. CPC H01L 21/02175; C23C 16/40; C23C 16/45553; C23C 16/56; H01L 21/0228; H01L 21/02348; H01L 21/0337; H01L 21/32139

(57) ABSTRACT

A method for forming ultraviolet (UV) radiation responsive metal-oxide containing film is disclosed. The method may include, depositing an UV radiation responsive metal oxide-containing film over a substrate by, heating the substrate to a deposition temperature of less than 400° C., contacting the substrate with a first vapor phase reactant comprising a metal component, a hydrogen component, and a carbon component, and contacting the substrate with a second vapor phase reactant comprising an oxygen containing precursor, wherein regions of the UV radiation responsive metal oxide-containing film have a first etch rate after UV irradiation and regions of the UV radiation responsive metal oxide-containing film not irradiated with UV radiation have a second etch rate, wherein the second etch rate is different from the first etch rate.

### CROSS-REFERENCE TO RELATED APPLICATIONS

This application is a continuation of, and claims priority to, U.S. patent application Ser. No. 17/545,047 filed Dec. 8, 2021, which is a divisional of U.S. patent application Ser. No. 16/206,589 filed Nov. 30, 2018 titled METHOD FOR FORMING AN ULTRAVIOLET RADIATION RESPONSIVE METAL OXIDE-CONTAINING FILM (now U.S. Pat. No. 11,217,444 issued Jan. 4, 2022), the disclosures of which are hereby incorporated by reference in their entirety.

### FIELD OF INVENTION

The present disclosure relates generally to methods for forming an ultraviolet (UV) radiation responsive metal oxide-containing film. The present disclosure also generally relates to methods for directly forming a patterned metal oxide-containing hard mask and semiconductor structures including a patterned metal oxide-containing hard mask.

### BACKGROUND OF THE DISCLOSURE

As semiconductor device structures trend towards smaller and smaller geometries, different patterning techniques have arisen. These techniques include self-aligned multiple patterning, spacer defined quadruple patterning, and ultraviolet lithography which may include, deep ultraviolet lithography (DUVL), extreme ultraviolet lithography (EUVL), and DUVL/EUVL combined with spacer defined double patterning. In addition, direct self-assembly (DSA) has been considered as an option for future lithography applications.

The patterning techniques described above may utilize at least one organic polymer resist disposed on a substrate to enable high resolution patterning of the substrate. To satisfy the requirements of both high resolution and low line-edge roughness, the polymer resist may commonly be a thin layer. However, such thin polymer resists may have several drawbacks. In particular, high resolution polymer resists may have a low etch resistance, i.e., high etch rates. This low etch resistance of the polymer resist makes the transfer of the patterned resist to the underlying layers more difficult. The issue of low etch resistance becomes greater when the advanced high-resolution polymer resists need to be further downscaled as the polymer resist may have an even lower etch resistance and etch selectivity.

In some applications it may be advantageous to transfer the pattern of the polymer resist to a hardmask. A hardmask is a material used in semiconductor processing as an etch mask instead of, or in addition to, the polymer or other organic “soft” resist materials. Hardmask materials commonly have a higher etch resistance and higher etch selectivity than polymer resists. However, hardmask patterning methods commonly involve indirect patterning techniques through the use of an intermediate polymer resist to define the hardmask pattern.

Accordingly, methods for forming a ultraviolet (UV) radiation responsive material which may be directly patterned and subsequently utilized as a hard mask material are desirable.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments of the disclosure, a method for forming an ultraviolet (UV) radiation responsive metal oxide-containing film is disclosed. The method may comprise: depositing a UV radiation responsive metal oxide-containing film over a substrate, the UV radiation responsive metal oxide-containing film having a substantially uniform etch rate, wherein depositing comprises: heating the substrate to a deposition temperature of less than 400° C.; contacting the substrate with a first vapor phase reactant comprising a metal component, a hydrogen component, and a carbon component; and contacting the substrate with a second vapor phase reactant comprising an oxygen precursor, wherein regions of the UV radiation responsive metal oxide-containing film have a first etch rate after UV irradiation and regions of the UV radiation responsive metal oxide-containing film not irradiated with UV radiation have a second etch rate, wherein the second etch rate is different from the first etch rate.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a non-limiting exemplary process flow demonstrating a method for depositing, irradiating, and patterning an UV responsive metal oxide-containing film according to the embodiments of the disclosure;

FIG. 2 illustrates a non-limiting exemplary sub-process flow demonstrating a cyclical deposition method for depositing an UV responsive metal oxide-containing film according to the embodiments of the disclosure;

FIG. 3 illustrates a non-limiting exemplary sub-process flow demonstrating a chemical vapor deposition method for depositing an UV responsive metal oxide-containing film according to the embodiments of the disclosure;

FIGS. 4A-4D illustrate cross-sectional schematic semiconductor structures formed by the process of forming, irradiating, and developing an UV responsive metal oxide-containing film according to the embodiments of the disclosure;

FIG. 5 illustrates a non-limiting exemplary process flow demonstrating a method for depositing, irradiating, and patterning an UV responsive hybrid material film according to the embodiments of the disclosure; and

FIG. 6 illustrates a non-limiting exemplary sub-process flow demonstrating a cyclical deposition method for depositing a UV responsive hybrid material film according to the embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term “substrate” may refer to any underlying material or materials that may be used, or upon which, a device, a circuit, or a film may be formed.

As used herein, the term “chemical vapor deposition” may refer to any process wherein a substrate is exposed to one or more volatile precursors, which react and/or decompose on a substrate surface to produce a desired deposition.

As used herein, the term “cyclic deposition” may refer to the sequential introduction of precursors (reactants) into a reaction chamber to deposit a film over a substrate and includes deposition techniques such as atomic layer deposition and cyclical chemical vapor deposition.

As used herein, the term “cyclical chemical vapor deposition” may refer to any process wherein a substrate is sequentially exposed to two or more volatile precursors, which react and/or decompose on a substrate to produce a desired deposition.

As used herein, the term “atomic layer deposition” (ALD) may refer to a vapor deposition process in which deposition cycles, preferably a plurality of consecutive deposition cycles, are conducted in a reaction chamber. Typically, during each cycle the precursor is chemisorbed to a deposition surface (e.g., a substrate surface or a previously deposited underlying surface such as material from a previous ALD cycle), forming a molecular monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition,” “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “film” and “thin film” may refer to any continuous or non-continuous structures and material deposited by the methods disclosed herein. For example, “film” and “thin film” could include 2D materials, nanolaminates, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

As used herein, the term “metalorganic” or “organometallic” are used interchangeably and may refer to organic compounds containing a metal component or a metalloid component. Organometallic compounds may be considered to be subclass of metalorganic compounds having direct metal-carbon bonds.

As used herein, the term “metal oxide-containing film” may refer to a film comprising at least one metal component and an oxygen component. The term “metal oxide-containing film” may also refer to a metal-oxide containing film comprising one or more additional metal components, one or more dopant species, and/or impurities.

As used herein, the term “metal component” may refer to both to an elemental metal component and a metalloid component, wherein a metalloid component may include, but is not limited to, a silicon component, a germanium component, a boron component, or an antimony component.

As used herein, the term “UV responsive metal-oxide-containing film” may refer to a metal-oxide containing film which when irradiated with UV radiation may absorb at least a portion of the UV radiation and undergo at least one of a physical or chemical alteration in response to the UV radiation stimulus.

As used herein, the term “crystalline film” may refer to a film which displays at least short range ordering or even long range ordering of the crystalline structure and includes single crystalline films as well as polycrystalline films. In contrast, as used herein, the term “amorphous film” may refer to a film which displays substantially no ordering of the structure of the film.

As used herein, the term “dopant precursor” may refer to a precursor comprising a dopant species which may alter the responsiveness of the UV radiation responsive metal oxide-containing film when irradiated with UV radiation.

As used herein, the term “etch rate” may refer to the rate of film removal by one or more of a wet etch process, a dry etch process, or a thermal etch process.

A number of example materials are given throughout the embodiments of the current disclosure, it should be noted that the chemical formulas given for each of the example materials should not be construed as limiting and that the non-limiting example materials given should not be limited by a given example stoichiometry.

The embodiments of the disclosure may provide methods for forming and irradiating a UV radiation responsive metal oxide-containing film. The irradiated metal oxide-containing film may be subsequently developed to form a metal-oxide containing hard mask without the need for an intermediate organic polymer resist and without the associated photolithographic processes required for forming and patterning the organic polymer.

Ultraviolet lithography (UVL) commonly utilizes organic polymer masking materials. For example, the UVL process may expose the organic polymer masking material to UV radiation which is at least partially absorb in the organic masking material and also in the underlying substrate, producing highly energetic photoelectrons and in turn a cascade of low-energy second electrons. These secondary electrons increase the chemical reactions in the organic polymer masking material which increases its sensitivity to UV radiation. However, the secondary electron pattern is random in nature and is superimposed on the optical image, resulting in a loss of resolution, an increase in line edge roughness (LER), and linewidth variation. Accordingly, alternative masking materials are desirable which are responsive to UV radiation but are less susceptible to secondary electron exposure effects. In addition, masking materials are desirable which are responsive to UV radiation while also maintaining structural rigidity and high etch resistance when exposed to common etchants utilized during semiconductor device fabrication. Further, UV responsive masking materials are desirable with improved adhesion to the underlying substrate which may remove the need for an intermediate adhesion promotion layer thereby simplifying the semiconductor device fabrication process.

Therefore the embodiments of the disclosure provide methods for forming and irradiating an UV radiation responsive metal oxide-containing film. The methods may comprise: depositing an ultraviolet (UV) radiation responsive metal oxide-containing film over a substrate, the UV radiation responsive metal oxide-containing film having a substantially uniform etch rate, wherein depositing comprises: heating the substrate to a deposition temperature of less than 400° C., contacting the substrate with a first vapor phase reactant comprising a metal component, a hydrogen component, and a carbon component; and contacting the substrate with a second vapor phase reactant comprising an oxygen precursor, wherein regions of the UV radiation responsive metal oxide-containing film have a first etch rate after UV irradiation and regions of the UV responsive metal oxide-containing film not irradiated with UV radiation have a second etch rate, wherein the second etch rate is different from the first etch rate.

As used herein, “UV radiation” may refer to electromagnetic radiation having a wavelength of less than 250 nanometers, or less than 200 nanometers, or less than 100 nanometers, or less than 50 nanometers, or less than 25 nanometers, or even less than 20 nanometers, or with a wavelength between approximately 10 nanometers and approximately 400 nanometers, or with a wavelength between approximately 10 nanometers and approximately 200 nanometers. In some embodiments the electromagnetic radiation may be in the range below 13.5 nanometers. As non-limiting examples, the UV radiation may have a wavelength of 193 nanometers, 248 nanometers, or 13.5 nanometers.

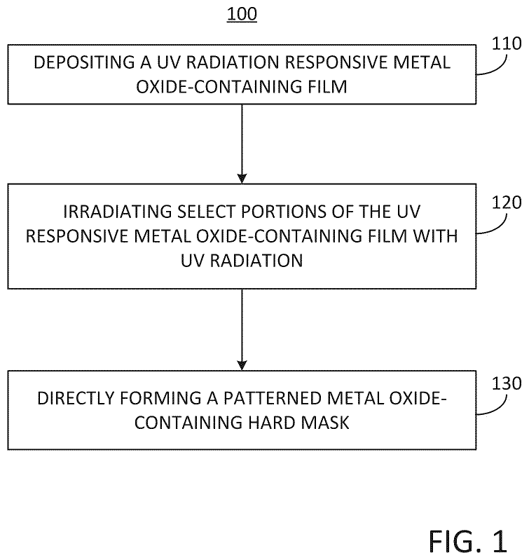

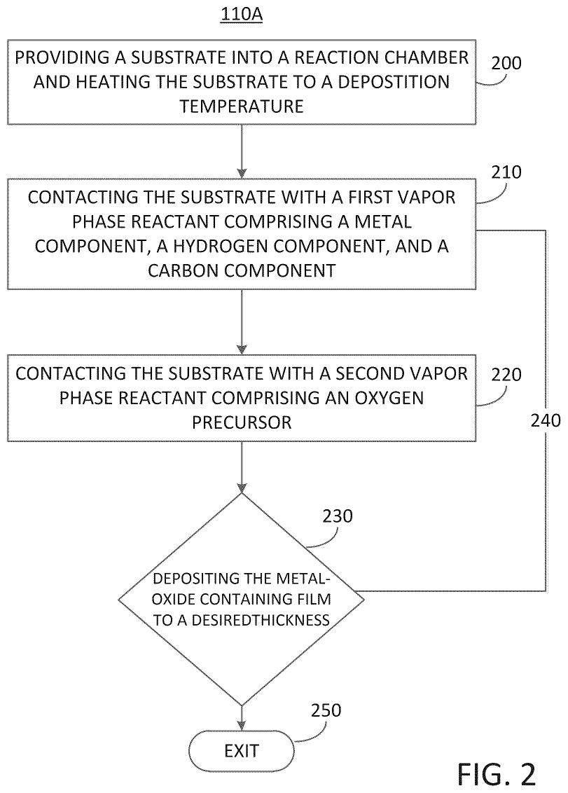

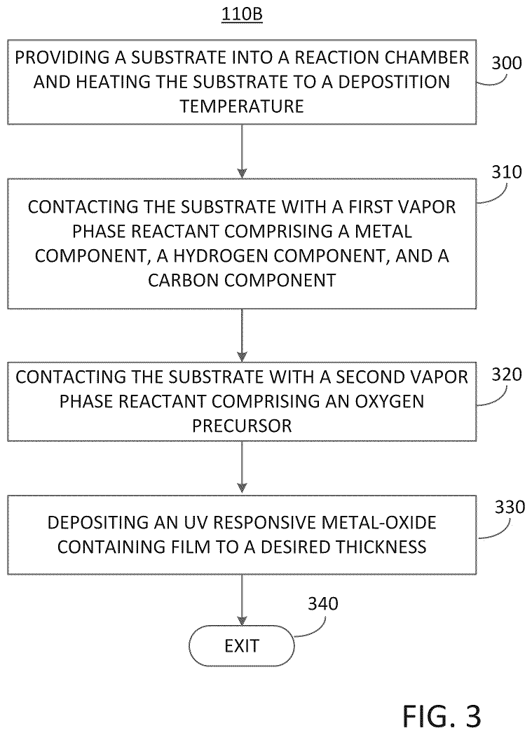

The embodiments of the disclosure are further described with reference to FIG. 1, which illustrates an exemplary process 100 for depositing an UV responsive metal oxide-containing film, irradiating select portions of the UV responsive metal oxide-containing with UV radiation, and directly forming a patterned metal oxide-containing hardmask mask, i.e., without the need for an intermediate organic polymer resist. In more detail, the exemplary process 100 may commence by means of a process block 110 comprising, depositing an UV radiation responsive metal oxide-containing film. The process block 110 is illustrated in greater detail with reference to FIG. 2 and FIG. 3, wherein FIG. 2 illustrates an exemplary cyclical deposition process 110A for depositing the UV responsive metal oxide-containing film and FIG. 3 illustrates an exemplary chemical vapor deposition process 110B for depositing the UV responsive metal oxide-containing film.

As a non-limiting example the UV responsive metal oxide-containing film may be deposited by cyclical deposition methods as described herein with reference to FIG. 2 which illustrates the deposition process 110A and its constituent sub-processes. The exemplary deposition process 110A may commence by means of a sub-process block 200 comprising, providing a substrate into a reaction chamber and heating the substrate to a deposition temperature.

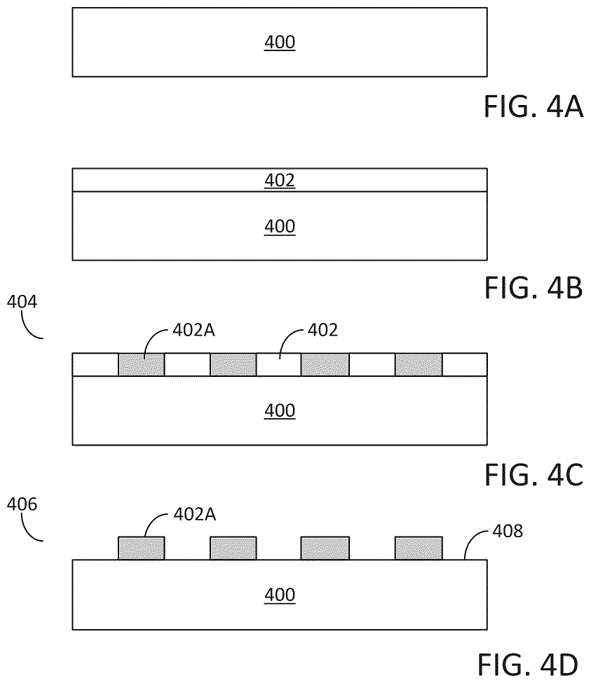

In some embodiments of the disclosure, the substrate may comprise a planar substrate (as illustrated by substrate 400 of FIG. 4A) or a patterned substrate including high aspect ratio features, such as, for example, trench structures and/or fin structures. The substrate may comprise one or more materials including, but not limited to, silicon (Si), germanium (Ge), germanium tin (GeSn), silicon germanium (SiGe), silicon germanium tin (SiGeSn), silicon carbide (SiC), or a group III-V semiconductor material, such as, for example, gallium arsenide (GaAs), gallium phosphide (GaP), or gallium nitride (GaN). In some embodiments, the substrate may comprise one or more dielectric materials, such as, but not limited, metal oxides, silicon oxides, silicon nitrides, and silicon oxynitrides. In some embodiments, the substrate may further one or more metals, metal nitrides, metal carbides, or mixtures thereof. In some embodiments of the disclosure, the substrate may comprise an engineered substrate wherein a surface semiconductor layer is disposed over a bulk support with an intervening buried oxide (BOX) disposed there between.

Patterned substrates may comprise substrates that may include semiconductor device structures formed into or onto a surface of the substrate, for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon (Si), silicon germanium (SiGe), silicon carbide (SiC), germanium tin (GeSn), germanium (Ge), or a group III-V semiconductor. Polycrystalline or amorphous surfaces may include dielectric materials, such as oxides, oxynitrides or nitrides, such as, for example, silicon oxides and silicon nitrides.

In some embodiments, the substrate may be disposed in a reaction chamber configured for a cyclical deposition process, such as, for example, a reaction chamber configured for an atomic layer deposition process or a reaction chamber configured for a cyclical chemical vapor deposition process. For example, ALD reactors, as well as CVD reactors, configured to provide the precursors in sequential manner may be utilized to deposit UV radiation responsive metal oxide-containing films employing a cyclic deposition process. According to some embodiments, a showerhead reactor may be used. According to some embodiments, cross-flow, batch, mini-batch, or spatial ALD reactors may be used.

In some embodiments of the disclosure, the exemplary cyclical deposition process 110A may be performed within a batch reactor. In some embodiments, a vertical batch reactor may be used. In other embodiments, a batch reactor comprises a mini-batch reactor configured to accommodate 10 or fewer wafers, 8 or fewer wafers, 6 or fewer wafers, 4 or fewer wafers, or 2 or fewer wafers. In some embodiments in which a batch reactor is used, wafer-to-wafer non-uniformity is less than 3% (1 sigma), less than 2%, less than 1%, or even less than 0.5%.

The exemplary cyclical deposition process 110A described herein may optionally be carried out in a reactor or reaction chamber connected to a cluster tool. In a cluster tool, because each reaction chamber is dedicated to one type of process, the temperature of the reaction chamber in each module can be kept constant, which improves the throughput compared to a reactor in which the substrate is heated up to the process temperature before each run. Additionally, in a cluster tool it is possible to reduce the time to pump the reaction chamber to the desired process pressure levels between substrates. In some embodiments of the disclosure, the exemplary cyclical deposition processes for the formation of a UV radiation responsive metal oxide-containing film disclosed herein may be performed in a cluster tool comprising multiple reaction chambers, wherein each individual reaction chamber may be utilized to expose the substrate to an individual precursor gas and the substrate may be transferred between different reaction chambers for exposure to multiple precursors gases, the transfer of the substrate being performed under a controlled ambient to prevent oxidation/contamination of the substrate. In some embodiments of the disclosure, the cyclical deposition processes of the current disclosure may be performed in a cluster tool comprising multiple reaction chambers, wherein each individual reaction chamber may be configured to heat the substrate to a different temperature.

A stand-alone reactor may be equipped with a load-lock. In that case, it is not necessary to cool down the reaction chamber between each run.

In some embodiments a cyclical deposition process may be a hybrid ALD/CVD or a cyclical CVD process. For example, in some embodiments, the growth rate of the ALD process may be low compared with a CVD process. One approach to increase the growth rate may be that of operating at a higher substrate temperature than that typically employed in an ALD process, resulting in some portion of a chemical vapor deposition process, but still taking advantage of the sequential introduction of precursors, such a process may be referred to as cyclical CVD. In some embodiments, a cyclical CVD process may comprise the sequential introduction of two or more precursors into the reaction chamber wherein there may be a time period of overlap between the two or more precursors in the reaction chamber resulting in both an ALD component of the deposition and a CVD component of the deposition.

Once the substrate is disposed within a suitable reaction chamber the sub-process 200 (FIG. 2) may continue by heating the substrate to a desired deposition temperature prior to film deposition. For example, the substrate may be heated to a substrate temperature of less than approximately 800° C., or less than approximately 600° C., or less than approximately 400° C., or less than approximately 350° C., or less than approximately 300° C., or less than approximately 250° C., or less than approximately 200° C., or less than approximately 150° C., or less than approximately 100° C., or less than approximately 50° C., or even less than approximately 25° C. In some embodiments of the disclosure, the substrate temperature during the deposition process may be between 25° C. and 250° C., or between 100° C. and 200° C. In some embodiments, the substrate temperature during the deposition process may be between 15° C. and 350° C., or between 20° C. and 300° C.

In addition to achieving a desired deposition temperature, i.e., a desired substrate temperature, the exemplary cyclical deposition process 110A may also regulate the pressure within the reaction chamber to obtain desirable characteristics of the deposited UV responsive metal oxide-containing film. For example, in some embodiments of the disclosure, the exemplary cyclical deposition process 110A may be performed within a reaction chamber regulated to a reaction chamber pressure of less than 100 Torr, or less than 10 Torr, or less than 1 Torr, or less than 0.1 Torr, or less than 0.01 Torr, or even less than 0.0001 Torr.

A non-limiting example embodiment of a cyclical deposition process may include atomic layer deposition (ALD), wherein ALD is based on typically self-limiting reactions, whereby sequential and alternating pulses of reactants are used to deposit about one atomic (or molecular) monolayer of material per deposition cycle. The deposition conditions and precursors are typically selected to provide self-saturating reactions, such that an absorbed layer of one reactant leaves a surface termination that is non-reactive with the gas phase reactants of the same reactants. The substrate is subsequently contacted with a different reactant that reacts with the previous termination to enable continued deposition. Thus, each cycle of alternated pulses typically leaves no more than about one monolayer of the desired material. However, as mentioned above, the skilled artisan will recognize that in one or more ALD cycles more than one monolayer of material may be deposited, for example, if some gas phase reactions occur despite the alternating nature of the process.

In an ALD-type process utilized for the formation of an UV radiation responsive metal oxide-containing film one deposition cycle may comprise exposing the substrate to a first vapor phase reactant, removing any unreacted first reactant and reaction byproducts from the reaction chamber, and exposing the substrate to a second vapor phase reactant, followed by a second removal step. In some embodiments of the disclosure, the first vapor phase reactant may comprise a metal component, a hydrogen component, and a carbon component, and the second vapor phase reactant may comprise an oxygen containing precursor.

Precursors may be separated by inert gases, such as argon (Ar) or nitrogen (N₂), to prevent gas-phase reactions between reactants and enable self-saturating surface reactions. In some embodiments, however, the substrate may be moved to separately contact a first vapor phase reactant and a second vapor phase reactant. Because the reactions self-saturate to some degree, strict temperature control of the substrates and precise dosage control of the precursors may not be required. However, the substrate temperature is preferably such that an incident gas species does not condense into monolayers nor decompose on the surface. Surplus chemicals and reaction byproducts, if any, are removed from the substrate surface, such as by purging the reaction space or by moving the substrate, before the substrate is contacted with the next reactive chemical. Undesired gaseous molecules can be effectively expelled from a reaction space with the help of an inert purging gas. A vacuum pump may be used to assist in the purging.

Upon heating the substrate to a desired deposition temperature, the exemplary cyclical deposition process 110A may continue with a cyclical deposition phase 240 by means of a sub-process block 210, which comprises contacting the substrate with a first vapor phase reactant and particularly, in some embodiments, contacting the substrate with a first vapor phase reactant comprising a metal component, a hydrogen component, and a carbon component.

In some embodiments of the disclosure, the first vapor phase reactant may comprise a metalorganic precursor, wherein the metalorganic precursor comprises a metal component, a hydrogen component, and a carbon component. In some embodiment, the first vapor phase reactant may comprise a metalorganic precursor including a metal component selected from the group comprising: aluminum, zinc, indium, bismuth, or antimony. In some embodiment, the first vapor phase reactant may comprise a metalorganic precursor including a metalloid component selected from the group comprising, silicon, or germanium.

In some embodiments of the disclosure, the first vapor phase reactant may comprise an aluminum (Al) component, i.e., the aluminum metalorganic precursor. For example, the aluminum metalorganic precursor may comprise at least one of trimethylaluminum (TMA), triethylaluminum (TEA), dimethylaluminumhydride (DMAH), dimethylaluminum isopropoxide (DMAI), or tritertbutylaluminum (TTBA).

In some embodiments of the disclosure, the first vapor phase reactant may comprise a zinc (Zn) component, i.e., the zinc metalorganic precursor. For example, the zinc metalorganic precursor may comprise at least one of dimethylzinc (ZnMe₂), diethylzinc (ZnEt₂), methylzinc isopropoxide (ZnMe(OPr)), or zinc acetate (Zn(CH₃CO₂)₂)

In some embodiments of the disclosure, the first vapor phase reactant may comprise an indium (In) component, i.e., the indium metalorganic precursor. For example, the indium metalorganic precursor may comprise at least one of trimethylindium (TMI), triethylindium (TEI), di-isopropylmethylindium (DIPMeIn), or ethyldimethylindium (EDMIn).

In some embodiments of the disclosure, the first vapor phase reactant may comprise a bismuth (Bi) component, i.e., the bismuth metalorganic precursor. For example, the bismuth metalorganic precursor may comprise at least one of a bismuth-alkoxide or a bismuth-silyamido. In some embodiments, the metalorganic bismuth precursor may be selected from the group comprising: [(dmb)₂Bi—O—Bi(dmb)₂]₂, tris(2,3-dimethyl-2-butyxy)bismuth(III), tris(tert-butoxy)bismuth(III), or tri (isopropoxy)bismuth(III). In some embodiments, the metalorganic bismuth precursor may be selected from the group comprising: Bi(N(SiMe₃)₂)₃, Bi(thd)₃, Bi(O^{t}Bu)₃, Bi(dmb)₃, or Bi(CH₂SiMe₃)₃. Metalorganic bismuth precursors are described in U.S. Pat. No. 7,713,584, issued to Hatanpaa et al., and incorporated by reference herein.

In some embodiments of the disclosure, the first vapor phase reactant may comprise an antimony (Sb) component, i.e., the antimony metalorganic precursor. For example, the antimony metalorganic precursor may comprise at least one of an antimony alkoxide, an antimony alkylamine, or an antimony alkyl. In some embodiments, the antimony metalorganic precursor may comprise at least one of Sb(N(CH₃)₂)₃, Sb(NMe₂)₃, Sb(NEr₂)₃, or Sb(NPr₂)₃. Metalorganic antimony precursors are described in U.S. Pat. No. 9,006,112, issued to Matero et al., and incorporated by reference herein.

In some embodiments of the disclosure, the first vapor phase reactant may comprise a silicon component, i.e., the silicon metalorganic precursor. For example, the silicon metalorganic precursor may comprise an alkylaminosilanes, such as, for example, a bisalkylaminosilane (e.g., bisdiethylaminosilane), an alkylaminosilane (e.g., di-isopropylaminosilane), or a trisalkylaminosilane (e.g., trisdimethylaminosilane).

In some embodiments of the disclosure, the first vapor phase reactant may comprise a germanium component, i.e., the germanium metalorganic precursor. For example, the germanium metalorganic precursor may comprise at least one of tetrakis(dimethylamino) germanium (TDMAGe), tetrakis(diethylamino) germanium (TDEAGe), or tetrakis(ethylmethylamino) germanium (TEMAGe).

In some embodiments of the disclosure, contacting the substrate with a first vapor phase reactant, e.g., the metalorganic precursor, may comprise contacting the substrate for a time period of between about 0.01 seconds and about 60 seconds, between about 0.05 seconds and about 10 seconds, or between about 0.1 seconds and about 5.0 seconds. In addition, during the contacting of the substrate with the first vapor phase reactant, the flow rate of the first vapor phase reactant may be less than 2000 sccm, or less than 500 sccm, or even less than 100 sccm. In addition, during the contacting of the first vapor phase reactant to the substrate the flow rate of the first vapor phase reactant may range from about 1 to 2000 sccm, from about 5 to 1000 sccm, or from about 10 to about 500 sccm.

Exemplary cyclical deposition process 110A of FIG. 2 may continue by purging the reaction chamber. For example, excess first vapor phase reactant and reaction byproducts (if any) may be removed from the surface of the substrate, e.g., by pumping with an inert gas. In some embodiments of the disclosure, the purge process may comprise a purge cycle wherein the substrate surface is purged for a time period of less than approximately 5.0 seconds, or less than approximately 3.0 seconds, or even less than approximately 2.0 seconds. Excess first vapor phase reactant and any possible reaction byproducts may be removed with the aid of a vacuum, generated by a pumping system in fluid communication with the reaction chamber.

Upon purging the reaction chamber with a purge cycle the exemplary cyclical deposition process 110A may continue with a second stage of the cyclical deposition phase 240 by means of a sub-process block 220 which comprises, contacting the substrate with a second vapor phase reactant, and particularly contacting the substrate with a second vapor phase reactant comprising an oxygen containing precursor (“the oxygen precursor”).

In some embodiments of the disclosure, the oxygen containing precursor may comprise at least one of water (H₂O), ozone (O₃), hydrogen peroxide (H₂O₂), molecular oxygen (O₂), atomic oxygen (O), nitrous oxide (N₂O), nitrogen dioxide (NO₂), sulfur trioxide (SO₃), or an oxygen based plasma, wherein the oxygen based plasma comprises atomic oxygen (O), oxygen ions, oxygen radicals, and excited oxygen species, and may be generated by the excitation (e.g., by application of RW power) of an oxygen containing gas. It should be noted that as used herein the term “vapor phase reactant” includes an excited plasma and the excited species comprising the plasma.

In some embodiments of the disclosure, contacting the substrate with the oxygen containing precursor may comprise, contacting the oxygen precursor to the substrate for a time period of between about 0.01 seconds and about 60 seconds, between about 0.05 seconds and about 10 seconds, or between about 0.1 seconds and about 5.0 seconds. In addition, during the contacting of the oxygen precursor with the substrate, the flow rate of the oxygen precursor may be less than 2000 sccm, or less than 500 sccm, or even less than 100 sccm. In addition, during the contacting the substrate with the oxygen precursor the flow rate of the oxygen precursor may range from about 1 to 2000 sccm, from about 5 to 1000 sccm, or from about 10 to about 500 sccm.

Upon contacting the substrate with the oxygen precursor, the exemplary cyclical deposition process 110A may proceed by purging the reaction chamber. For example, excess oxygen precursor and reaction byproducts (if any) may be removed from the surface of the substrate, e.g., by pumping whilst flowing an inert gas. In some embodiments of the disclosure, the purge process may comprise purging the substrate surface for a time period of between approximately 0.1 seconds and approximately 10 seconds, or between approximately 0.5 seconds and approximately 3 seconds, or even between approximately 1 second and 2 seconds.

Upon completion of the purge of the second vapor phase reactant, i.e., the oxygen precursor (and any reaction byproducts) from the reaction chamber, the cyclic deposition phase 240 may continue by means of a decision gate 230, wherein the decision gate 230 is dependent on the thickness of the UV radiation responsive metal oxide-containing film deposited. For example, if the UV radiation responsive metal oxide-containing film is deposited at an insufficient thickness for a desired application, then the cyclical deposition phase 240 may be repeated by returning to the sub-process block 210 and continuing through a further deposition cycle, wherein a unit deposition cycle may comprise, contacting the substrate with a first vapor phase reactant, such as, for example, a metalorganic precursor (sub-process block 210), purging the reaction chamber, contacting the substrate with an oxygen containing precursor (sub-process block 220), and again purging the reaction chamber. A unit deposition cycle of cyclical deposition phase 240 may be repeated one or more times until a desired thickness of a UV radiation responsive metal oxide-containing film is deposited over the substrate. Once the UV radiation responsive metal oxide-containing film has been deposited to the desired thickness the exemplary deposition process 110 may exit via a process block 250 and the substrate, with the UV radiation responsive metal oxide-containing film thereon, may be subjected to further processing for the formation of a metal oxide-containing hard mask material.

It should be appreciated that in some embodiments of the disclosure, the order of contacting of the substrate with the first vapor phase reactant (e.g., the metalorganic precursor) and the second vapor phase reactant (e.g., the oxygen precursor) may be such that the substrate is first contacted with the second vapor phase reactant followed by the first vapor phase reactant. In addition, in some embodiments, the cyclical deposition phase 240 of exemplary cyclical deposition process 110A may comprise, contacting the substrate with the first vapor phase reactant one or more times prior to contacting the substrate with the second vapor phase reactant one or more times. In addition, in some embodiments, the cyclical deposition phase 240 of exemplary cyclical deposition process 110A may comprise, contacting the substrate with the second vapor phase reactant one or more times prior to contacting the substrate with the first vapor phase reactant one or more times.

In some embodiments, the cyclical deposition phase 240 may further comprise contacting the substrate with a third vapor phase reactant comprising at least a metal component wherein the metal component in the third vapor phase reactant may be different from the metal component in the first vapor phase reactant. The addition of a third vapor phase reactant comprising at least a metal component allows for the deposition of mixed metal oxides, or mixed metalloid oxides, or a mixture of a metal oxide and a metalloid oxide.

In alternative embodiments of the disclosure, the UV radiation responsive metal oxide-containing film may be deposited by a chemical vapor deposition process and an exemplary chemical vapor deposition process 110B and the constituent sub-processes of chemical vapor deposition process 110B are described with reference to FIG. 3.

In more detail, the exemplary chemical vapor deposition process 110B may commence by means of a sub-process block 300 comprising, providing the substrate into a reaction chamber of a semiconductor processing apparatus configured for chemical vapor deposition processes and heating the substrate to a desired deposition temperature. The substrate may comprise all the forms of substrates and substrate material(s) as described with reference to exemplary cyclical deposition process 110A of FIG. 2. An exemplary chemical vapor deposition process for depositing a UV radiation responsive metal oxide-containing film may comprise heating the substrate to a deposition temperature of less than 800° C., or less than 600° C., or less than 400° C., or less than 350° C., or less than 300° C., or less than 250° C., or less than 200° C., or less than 150° C., or less than 100° C., or less than 50° C., or even less than 25° C. In some embodiments of the disclosure, the substrate temperature during the deposition process may be between 25° C. and 250° C., or between 100° C. and 200° C.

In addition to achieving a desired deposition temperature, i.e., a desired substrate temperature, the exemplary CVD deposition process 110B may also regulate the pressure within the reaction chamber to obtain desirable characteristics of the deposited UV responsive metal oxide-containing film. For example, in some embodiments of the disclosure, the exemplary CVD process 110B may be performed within a reaction chamber regulated to a reaction chamber pressure of less than 100 Torr, or less than 10 Torr, or less than 1 Torr, or less than 0.1 Torr, or less than 0.01 Torr, or even less than 0.0001 Torr.

Upon achieving the desired deposition temperature and reactor pressure, the exemplary chemical vapor deposition process 110B may continue by performing the sub-process block 310 and the sub-process block 320 which comprises, contacting the substrate with a first vapor phase reactant comprising a metal component, a hydrogen component, and a carbon component (sub-process block 310), and further comprises, contacting the substrate with a second vapor phase reactant comprising an oxygen precursor (sub-process block 320).

In some embodiments of the disclosure, the sub-process block 310 and the sub-process block 320 are performed concurrently, in other words, the substrate may be contacted with both the first vapor phase reactant and the second vapor phase reactant concurrently. For example, the first vapor phase reactant may be introduced into the reaction chamber whilst simultaneously also introducing the second vapor phase reactant into the reaction chamber such that the first vapor phase reactant and the second vapor phase reactant are co-flowed simultaneously into the reaction chamber and a gas mixture comprising at least the first vapor phase reactant and the second vapor phase reactant may contact the substrate disposed within the reaction chamber.

In some embodiments, the flow rate of the first vapor phase reactant may be less than 2000 sccm, or less than 500 sccm, or even less than 100 sccm. In some embodiments, the flow rate of the first vapor phase reactant may be from about 1 to about 2000 sccm, from about 5 to about 1000 sccm, or from about 10 to about 500 sccm. In some embodiments, the flow rate of the second vapor phase reactant may be less than 2000 sccm, or less than 500 sccm, or even less than 100 sccm. In some embodiments, the flow rate of the second vapor phase reactant may be from about 1 to about 2000 sccm, from about 5 to about 1000 sccm, or from about 10 to about 500 sccm.

In alternative embodiments, the exemplary CVD process 110B may first introduce the first vapor phase reactant into the reaction chamber (sub-process block 310), followed subsequently by introducing the second vapor phase reactant into the reaction chamber (sub-process block 320). Alternatively, the exemplary CVD process 100B may first introduce the second vapor phase reactant into the reaction chamber (sub-process block 320), followed subsequently by introducing the first vapor phase reactant into the reaction chamber (sub-process block 310).

In exemplary chemical vapor deposition process 110B and particular in sub-process block 310 comprising contacting the substrate with a first vapor phase reactant, the first vapor phase reactant may comprise a metalorganic precursor comprising, a metal component, a hydrogen component, and a carbon component. In some embodiment, the first vapor phase reactant may comprise a metalorganic precursor including a metal component selected from the group comprising: aluminum, zinc, indium, bismuth, or antimony. In some embodiments, the first vapor phase reactant may comprise a metalorganic precursor including a metalloid component selected from the group comprising: silicon, or germanium.

The exemplary chemical vapor deposition process 100B and particularly sub-process block 310 may utilize all the metalorganic precursors as previously described with reference to cyclical deposition process 110A and therefore are not described again in relation to the exemplary CVD process 110B.

In addition, in exemplary chemical vapor deposition process 110B and particular in sub-process block 320 comprising contacting the substrate with a second vapor phase reactant, the second vapor phase reactant may comprise an oxygen precursor, and may utilize all the oxygen precursors previously described with reference to cyclical deposition process 110A and there are not described again in relation to the exemplary CVD process 110B.

The exemplary chemical vapor deposition process 110A may continue by means of process block 330 comprising, depositing an UV responsive metal oxide-containing film to a desired thickness. For example, contacting the substrate (at a desired substrate temperature) to the first vapor phase reactant and the second vapor phase reactant may result in the deposition of the UV responsive metal-oxide containing film on the upper exposed surface of the substrate and the exemplary CVD process may continue for a time period until a sufficient thickness of the UV responsive metal oxide-containing film is deposited, at which point the exemplary chemical vapor deposition process 110B may exit via process block 340 and the UV responsive metal oxide-containing film may be subjected to further process to form a patterned metal oxide-containing hardmask.

The exemplary cyclical deposition process 110A (FIG. 2) and the exemplary chemical vapor deposition process 110B (FIG. 3) may both further comprise an addition sub-process comprising, contacting the substrate with one or more dopant precursors.

As a non-limiting example, the cyclical deposition process 110A may further comprise contacting the substrate with one or more dopant precursors at any stage of the cyclical deposition phase 240. For example, the substrate may be contacted with one or more dopant precursors, prior to contacting the substrate with the first vapor phase reactant, or prior to contacting the substrate with the second vapor phase reactant, or subsequently to contacting the substrate with the second vapor phase reactant. Alternatively, the substrate may be contacted with one or more dopant precursors concurrently with contacting the substrate with the first vapor phase reactant and/or the substrate may be contacted with the one or more dopant precursors concurrently with contacting the substrate with the second vapor phase reactant. Alternatively one or more unit cycles of cyclic deposition phase 240 may be performed before contacting the substrate with the one or more dopant precursors, for example, a unit cycle of cyclical deposition phase 240 may be repeated one or more time, two or more time, five or more times, and subsequently the substrate may be contacted with the one or more dopant precursors.

As a further non-limiting example, the chemical vapor deposition process 110B may further comprise contacting the substrate with one or more dopant precursors at any stage of the chemical vapor deposition process 110B. For example, the first vapor phase reactant, the second vapor phase reactant, and the one or more dopant precursors may be simultaneously introduced into the reaction chamber and contact the substrate as a gas mixture comprising at least the first vapor phase reactant, the second vapor phase reactant, and the one or more dopant precursors. Alternatively, the one or more dopant precursors may contact the substrate prior to the first vapor phase reactant, followed by the second vapor phase reactant, or conversely the one or more dopant precursors may contact the substrate prior to the second vapor phase reactant, followed by the first vapor phase reactant, or any and all sequences that may be envisioned for contacting the substrate with the first vapor phase reactant, the second vapor phase reactant, and the one or more dopant precursors.

The one or more dopant precursors may contact the substrate in order to introduce one or more dopants into the UV responsive metal oxide-containing film which may alter the responsiveness of the UV radiation responsive metal oxide-containing film when irradiated with UV radiation. For example, in some embodiments, the introduction of one or more dopants into the UV responsive metal oxide-containing film may increase the UV responsivity of the metal-oxide containing film by greater than 50%, or greater than 100%, or even greater than 200%.

In some embodiments of the disclosure, the one or more dopant precursors may introduce into the UV radiation responsive metal oxide-containing film an additional metal oxide dopant, an additional metal dopant, or an alkyl silicon compound dopant. For example, the addition of dopants into the UV radiation responsive metal oxide-containing film may introduce structures and/or bond and/or groups to the metal-oxide containing film which improves the UV responsivity of the metal oxide-containing film.

In some embodiment of the disclosure, contacting the substrate with one or more dopant precursors may further comprise introducing an additional metal oxide dopant into the UV responsive metal oxide-containing film. For example, the additional metal oxide dopant may comprise at least one of an aluminum oxide, a zinc oxide, an indium oxide, a bismuth oxide, an antimony oxide, a silicon oxide, or a germanium oxide. In some embodiments, the additional metal oxide dopant may comprise a different metal oxide to that comprising the metal-oxide containing material. For example, a metalorganic precursor may be utilized to introduce the additional metal oxide dopant and such a metalorganic precursor may be different to that utilized as the first vapor phase reactant employed for depositing the metal-oxide containing film.

In some embodiment of the disclosure, contacting the substrate with one or more dopant precursors may further comprise introducing an additional metal dopant into the UV responsive metal oxide-containing film. For example, the additional metal dopant may comprise at least one of aluminum, zinc, indium, bismuth, antimony, silicon, or germanium. In some embodiments, the additional metal dopant may comprise tin.

In some embodiment of the disclosure, contacting the substrate with one or more dopant precursors may further comprise introducing an alkyl silicon compound dopant into the UV responsive metal oxide-containing film. In some embodiments, the alkyl silicon compound dopant may be selected from the group comprising: DSBAS di-sec-butylaminosilane (^{s}Bu₂N)SiH₃, BDEAS Bis(diethylamino)silane SiH₂(NEt₂)₂, BDMAS Bis(dimethylamino)silane SiH₂(NMe₂)₂, TriDMAS Tris(diethylamino)silane SiH(NMe₂)₃, Bis(trimethylsilylamino)silane SiH₂(NHSiMe₃)₂, TEAS Tetrakis(ethylamino)silane Si(NHEt)₄, TEOS Tetrakis(ethoxy)silane Si(OEt)₄, BTESE Bis(triethoxysilyl)ethane (EtO)₃Si—CH₂—CH₂—Si(OEt)₃.

In some embodiments of the disclosure, the silicon compound dopant is an aminosilane of the general formula (R₁R₂N)ₙSiH₄₋ₓ, where x is comprised between 1 and 4, where R1 and R2 are independently H or a C1-C6 linear, branched or cyclic carbon chains. Preferably the silicon compound dopant is an aminosilane of the general formula (R₁R₂N)ₙSiH₂, where R1 and R2 are preferably independently selected from C1-C4 linear, branched or cyclic carbon chains. In some embodiments the alkylaminosilane is bis(diethylamino)silane (BDEAS), bis(dimethylamino)silane (BDMAS) or tris(dimethylamino)silane (TriDMAS).

In some embodiments of the disclosure, the UV responsive metal oxide-containing film may be deposited to a thickness of greater than 1 nanometer, or greater than 5 nanometers, or greater than 10 nanometers, or greater than 20 nanometers. In some embodiments, the UV responsive metal oxide-containing film may be deposited between a thickness of 0.5 nanometers to 50 nanometers, or between a thickness of 1 nanometer to 30 nanometers, or between a thickness of 1 nanometer to 20 nanometers, or even between a thickness of 2 nanometers to 15 nanometers.

In some embodiments of the disclosure, the UV responsive metal oxide-containing film, as illustrated by film 402 of FIG. 4A, may be deposited over a substantial portion of the upper surface of a substrate 400. In some embodiments, the UV responsive metal-oxide containing film may be deposited only over select portions of the upper surface of the substrate 400 (not shown). In some embodiments, the UV responsive metal oxide-containing film 402 may have a substantially uniform etch rate as-deposited, i.e., a uniform etch prior to any UV irradiating process, wherein a substantially uniform etch rate may refer to an etch rate of the overall UV responsive metal oxide-containing film within a range of greater than 1 nanometer/minute, or greater than 5 nanometers/minute, or greater than 10 nanometers/minute, or greater than 20 nanometers/minute, or greater than 30 nanometers/minute, or greater than 50 nanometers/minute, or greater than 100 nanometers/minute or even greater than 150 nanometers/minute. In other embodiments, the UV responsive metal oxide-containing film material after radiation may have etch rate within a range of greater than 1 nanometer/minute, or greater than 5 nanometers/minute, or greater than 10 nanometers/minute, or greater than 20 nanometers/minute, or greater than 30 nanometers/minute, or greater than 50 nanometers/minute, or greater than 100 nanometers/minute or even greater than 150 nanometers/minute.

In some embodiments of the disclosure, depositing an UV radiation responsive metal oxide-containing film may comprise depositing at least one of an aluminum oxide, a zinc oxide, an indium oxide, a bismuth oxide, a silicon oxide, a germanium oxide, or an antimony oxide, and their corresponding doped counterparts. The UV radiation responsive metal oxide-containing films deposited according to the embodiments of the disclosure may conventionally be considered as poor quality films due to impurity concentration, wet etch rate, electrical properties, etc. However, the UV radiation responsive metal oxide-containing films deposited according to the embodiments of the disclosure may be utilized as highly UV responsive films. In contrast to prior methods of forming metal oxide-containing films the methods of the current disclosure may utilize process conditions which result in what would commonly be referred to as a “poor quality” film, the process conditions including, for example, incomplete reactions, partial CVD reactions, precursor decomposition, or incomplete precursor saturation. However, the employment of such process conditions not normally considered for the formation of metal-oxide containing films results in UV responsive metal oxide-containing films.

In some embodiments, the UV radiation responsive metal oxide-containing film is deposited to have a desired atomic percentage (atomic-%) of carbon, for example, the carbon may be introduced into the film from the first vapor phase precursors having a carbon component. For example, the UV responsive metal oxide-containing film may have a carbon concentrations greater than 1 atomic-%, or greater than 5 atomic-%, or greater than 10 atomic-%, or greater than 20 atomic-%, or greater than 30 atomic-%, or even greater than 40 atomic-%. In addition, in some embodiments, the UV radiation responsive metal oxide-containing film is deposited to have a desired atomic percentage (atomic-%) of hydrogen, for example, hydrogen may be introduced into the film from the first vapor phase precursors having a hydrogen component. For example, the UV responsive metal oxide-containing film may have a hydrogen concentration greater than 1 atomic-%, or greater than 5 atomic-%, or greater than 10 atomic-%, or greater than 20 atomic-%, or greater than 30 atomic-%, or even greater than 40 atomic-%. In addition, in some embodiments, the UV responsive metal oxide-containing film is deposited with a desired atomic percentage (atomic-%) of dopant species, such as, for example, an additional metal oxide dopant, an additional metal dopant, or an alkyl silicon compound dopant. Therefore, the UV responsive metal oxide-containing film may have a concentration of intentionally incorporated dopant species greater than 1 atomic-%, or greater than 5 atomic-%, or greater than 10 atomic-%, or greater than 20 atomic-%, or greater than 30 atomic-%, or even greater than 40 atomic-%.

In some embodiments, the UV responsive metal oxide-containing film may be substantially free of tin (Sn). For example, the UV responsive metal oxide-containing film may have a tin concentration of less than 20 atomic-%, or less than 10 atomic-%, or less than 5 atomic-%, or less than 1 atomic-%, or less than 0.5 atomic-%, or less than 0.1 atomic-%, or even less than 0.001 atomic-%.

In some embodiments of the disclosure, depositing the UV responsive metal oxide-containing film may further comprise depositing an amorphous UV responsive metal oxide-containing film, i.e., the film displays substantially no ordering of the structure of the film. For example, x-ray diffraction (XRD) analysis of the as-deposited UV responsive metal-oxide containing film may result in data which comprises no discernable peaks corresponding to a crystallographic direction in the film. In alternative embodiments, depositing the UV responsive metal oxide-containing film may further comprise depositing a crystalline UV responsive metal oxide-containing film, i.e., the film may display at least short range ordering or even long range ordering and includes single crystalline films as well as polycrystalline films. For example, x-ray diffraction (XRD) analysis of the as-deposited UV responsive metal oxide-containing film may result in data in which discernable peaks are observed corresponding to characteristic crystallographic direction(s).

Upon depositing the UV radiation responsive metal oxide-containing film the exemplary process 100 of FIG. 1 may continue by means of a process block 120 comprising, irradiating select portions of the UV responsive metal oxide-containing film with UV radiation.

In more detail, the substrate 400 with the UV responsive metal oxide-containing films 402 thereon (FIG. 4B) may be disposed within an UV patterning tool. In some embodiments, the UV responsive metal oxide-containing film may be deposited within a first reaction chamber and subsequently transferred to the UV patterning tool. In some embodiments, the reaction chamber configured for deposition of the UV responsive metal oxide-containing film and the UV patterning tool may form a clustered tool such that the transfer of the substrate with the UV responsive metal oxide-containing film disposed thereon is performed under a controlled ambient, i.e., without exposure to external conditions.

Once disposed within the UV patterning tool the methods of the disclosure may comprise, irradiating select portions of the UV radiation responsive metal oxide-containing film with UV radiation thereby forming a metal oxide-containing film with irradiated portions having a first etch rate and non-irradiated portions having a second etch rate different from the first etch rate. For example, FIG. 4C illustrates a semiconductor structure 404 which comprises a substrate 400, non-irradiation portions of the UV responsive metal oxide-containing film 402, and UV irradiated portions of the UV responsive metal oxide-containing film 402A. In some embodiments, the UV irradiated portions 402A have a first etch rate which is less than the second etch rate of the non-irradiated portions 402. In some embodiments, the UV irradiated portions 402A have a first etch rate which is greater than the second etch rate of the non-irradiated portions 402. In some embodiments of the disclosure, the etch selectivity between the irradiated portions 402A and the non-irradiated portions 402 may be greater than 2:1, or greater than 5:1, or greater than 8:1, or greater than 10:1, or greater than 15:1, or greater than 20:1, or even greater than 50:1. In alternative embodiments, the etch selectively between the non-irradiated portions 402 and the irradiated portions 402A may be greater than 2:1, or greater than 5:1, or greater than 8:1, or greater than 10:1, or greater than 15:1, or greater than 20:1, or even greater than 50:1.

In some embodiments, irradiating select portions of the UV responsive metal oxide-containing film to UV radiation further comprises at least partially crystallizing the UV irradiated portions 402A. In some embodiments, irradiating select portions of the UV responsive metal oxide-containing film to UV radiation further comprises increasing the etch resistance or the rigidity of the UV irradiated portions 402A. For example, in some embodiments the UV responsive metal oxide-containing film may be deposited as an amorphous film and irradiating select portions of the UV response metal oxide-containing film may stimulate crystallization of the UV responsive metal oxide-containing film.

Once the UV responsive metal oxide-containing film has been irradiated in select regions to UV radiation the exemplary method 100 of FIG. 1 may continue by means of a process block 130 comprising, directly forming a patterned metal oxide-containing hard mask. For example, the methods of the disclosure may further comprise directly forming a patterned metal oxide-containing hard mask by developing the UV responsive metal oxide-containing film to remove one of the irradiated portions or the non-irradiated portions.

In more detail, in some embodiments of the disclosure, the semiconductor structure 404 of FIG. 4C may be developed to remove either the irradiated portions 402A or the non-irradiation portions 402. For example, the developing process for removing select portions of the UV responsive metal oxide-containing film may comprise an etch process, such as, for example, one or more of a wet etch process (e.g., exposure to a wet etchant solution), a dry etch process (e.g., exposure to a plasma based etchant or non-plasma based etchant in gas phase), or a thermal etch process (e.g., heating the semiconductor structure 404). As a non-limiting example, the irradiated portions 402A may have first etch rate which may be less than a second etch rate of the non-irradiated portions 402 and therefore during exposure to an etching process the non-irradiated portions will be removed at a higher rate than the irradiated portions 402A allowing for the complete removal of the non-irradiated portions 402A whilst maintaining at least a portion of the irradiation portions 402A, as illustrated by semiconductor structure 406 of FIG. 4D which comprises the substrate 400 and a patterned metal oxide-containing hard mask 402A covering select portions of the surface of the substrate 400 while the remaining portions of the substrate surface 408 are exposed for subsequent processing. As a non-limiting example, removing select portions of the UV irradiated metal oxide-containing film may comprise a dry plasma etching process utilizing one or more of a chlorine chemistry or a fluorine chemistry. As a further non-limiting example, removing select portions of the UV irradiated metal-oxide containing film may comprise a wet etch process utilizing hydrochloric acid, for example. In some embodiments, the patterned metal oxide-containing hard mask 402A may comprise an at least partially crystalline film.

In alternative embodiments of the disclosure, the deposited UV responsive film utilized to form the patterned hard mask may comprise a hybrid material, wherein a hybrid material comprises both an inorganic component and an organic component and includes materials such as, for example, inorganic/organic nanolaminates and metal organic frameworks. As with the exemplary embodiments disclosed herein relating to UV responsive metal oxide-containing films, an UV responsive hybrid material may be deposited, selectively exposed to UV radiation, and patterned to form a hybrid material hard mask.

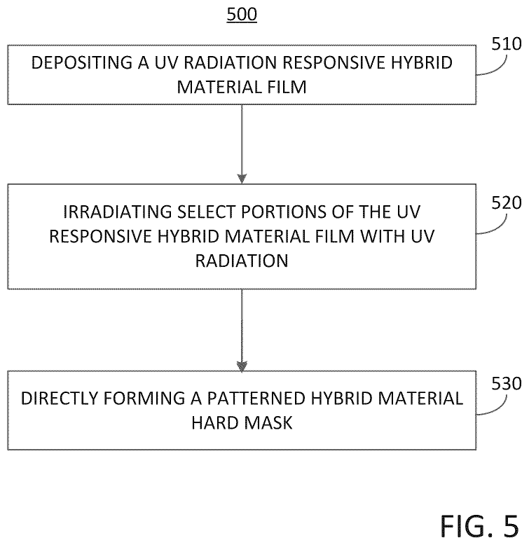

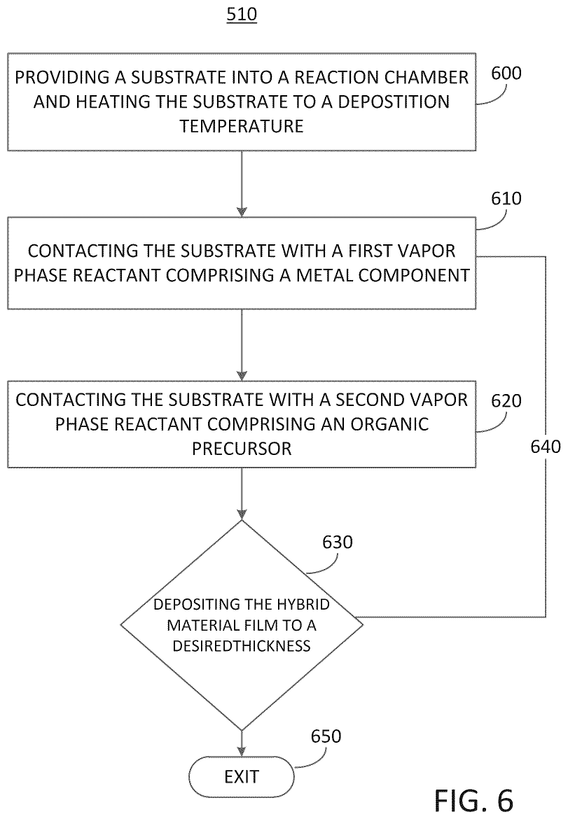

In more detail, FIG. 5 illustrates an exemplary process 500 for depositing an UV responsive hybrid material, irradiating select portions of the UV responsive hybrid material film with UV radiation, and directly forming a patterned hybrid material hardmask mask, i.e., without the need for an intermediate organic polymer resist. In more detail, the exemplary process 500 may commence by means of a process block 510 comprising, depositing a UV radiation responsive hybrid material. The process block 510 is illustrated in greater detail with reference to FIG. 6 which illustrates an exemplary cyclical deposition process 510 for depositing the UV responsive hybrid material.

The exemplary cyclical deposition process 510 of FIG. 6 utilized for deposition an UV responsive hybrid material may commence with a process block 600 comprising, providing a substrate into a reaction chamber and heating the substrate to a deposition temperature. The substrate and the substrate material(s) may comprise those previously described herein with reference to method 100 of FIG. 1. In some embodiments, the substrate may disposed within a reaction chamber configured for a cyclical deposition process, such as a reaction chamber configured for an atomic layer deposition process, or a reaction chamber configured for a cyclical chemical vapor deposition process. In some embodiments, the substrate may heated to a deposition temperature of less than approximately 800° C., or less than approximately 600° C., or less than approximately 400° C., or less than approximately 350° C., or less than approximately 300° C., or less than approximately 250° C., or less than approximately 200° C., or less than approximately 150° C., or less than approximately 100° C., or less than approximately 50° C., or even less than approximately 25° C. In some embodiments of the disclosure, the substrate temperature during the deposition process may be between 25° C. and 250° C., or between 100° C. and 200° C. In some embodiments, the substrate temperature during the deposition process may be between 15° C. and 350° C., or between 20° C. and 300° C.

Upon heating the substrate to a desired deposition temperature, the exemplary cyclical deposition process 510 may continue with a cyclical deposition phase 640 by means of a sub-process block 610, which comprises contacting the substrate with a first vapor phase reactant and particularly, in some embodiments, contacting the substrate with a first vapor phase reactant comprising a metal component.

In some embodiments of the disclosure, the first vapor phase reactant may comprise a metalorganic precursor, wherein the metalorganic precursor comprises a metal component, a hydrogen component, and a carbon component. In some embodiment, the first vapor phase reactant may comprise a metalorganic precursor including a metal component selected from the group comprising: aluminum, zinc, indium, silicon, germanium, bismuth, or antimony. The metalorganic precursors utilized for cyclical deposition of a hybrid material may be same as those previously described with reference to cyclical deposition process 110A of FIG. 2 and therefore are not repeated in relation to exemplary cyclical deposition process 510. In alternative embodiments, the first vapor phase reactant may comprise a halide precursor, such as least one of a metal chloride, a metal iodide, a metal bromide, or a metal fluoride.

In some embodiments of the disclosure, contacting the substrate with a first vapor phase reactant, e.g., the metal precursor, may comprise contacting the substrate for a time period of between about 0.01 seconds and about 60 seconds, between about 0.05 seconds and about 10 seconds, or between about 0.1 seconds and about 5.0 seconds. In addition, during the contacting of the substrate with the first vapor phase reactant, the flow rate of the first vapor phase reactant may be less than 2000 sccm, or less than 500 sccm, or even less than 100 sccm. In addition, during the contacting of the first vapor phase reactant to the substrate the flow rate of the first vapor phase reactant may range from about 1 to 2000 sccm, from about 5 to 1000 sccm, or from about 10 to about 500 sccm.

Exemplary cyclical deposition process 510 of FIG. 6 may continue by purging the reaction chamber. For example, excess first vapor phase reactant and reaction byproducts (if any) may be removed from the surface of the substrate, e.g., by pumping with an inert gas. In some embodiments of the disclosure, the purge process may comprise a purge cycle wherein the substrate surface is purged for a time period of less than approximately 5.0 seconds, or less than approximately 3.0 seconds, or even less than approximately 2.0 seconds. Excess first vapor phase reactant and any possible reaction byproducts may be removed with the aid of a vacuum, generated by a pumping system in fluid communication with the reaction chamber.

Upon purging the reaction chamber with a purge cycle the exemplary cyclical deposition process 510 may continue with a second stage of the cyclical deposition phase 640 by means of a sub-process block 620 which comprises, contacting the substrate with a second vapor phase reactant, and particularly contacting the substrate with a second vapor phase reactant comprising an organic precursor (“the organic precursor”).

In some embodiments of the disclosure, the organic precursor may comprise a homobifunctional compound, such as, for example, a diol, or a diamine. In some embodiments, the organic precursor may comprise at least one of ethylene glycol or ethylene diamine. In some embodiments of the disclosure, the organic precursor may comprise a heterobifunctional compound, such as, an alcoholamine (e.g., ethanolamine). In some embodiments, the organic precursor may comprise anhydrides, such as, maleic anhydride. In some embodiments of the disclosure, the organic precursor may be selected or tailored on the basis of the UV wavelength utilized in exposing the UV responsive hybrid material. In some embodiments of the disclosure, the organic precursor may comprise saturated or non-saturated, aliphatic or aromatic, cyclic or non-cyclic C1-C10 hydrocarbon, C2-C10 hydrocarbon, C3-C10 hydrocarbon, C4-C10 hydrocarbon, C5-C10 hydrocarbon, C1-C5 hydrocarbon, C2-C5 hydrocarbon, C3-C5 hydrocarbon, C4-C6 hydrocarbon, C5-C7 hydrocarbon, C1-C3 hydrocarbon, C2-C4 hydrocarbon functionalized with at least two functional groups such as —OH or —NH₂. In some embodiments the organic precursor is functionalized C2 hydrocarbon such as ethanolamine.

In some embodiments of the disclosure, contacting the substrate with the organic precursor may comprise, contacting the organic precursor to the substrate for a time period of between about 0.01 seconds and about 60 seconds, between about 0.05 seconds and about 10 seconds, or between about 0.1 seconds and about 5.0 seconds. In addition, during the contacting of the substrate to the organic precursor, the flow rate of the organic precursor may be less than 2000 sccm, or less than 500 sccm, or even less than 100 sccm. In addition, during the contacting the substrate with the organic precursor the flow rate of the oxygen precursor may range from about 1 to 2000 sccm, from about 5 to 1000 sccm, or from about 10 to about 500 sccm.

Upon contacting the substrate with the organic precursor, the exemplary cyclical deposition process 510 may proceed by purging the reaction chamber. For example, excess organic precursor and reaction byproducts (if any) may be removed from the surface of the substrate, e.g., by pumping whilst flowing an inert gas. In some embodiments of the disclosure, the purge process may comprise purging the substrate surface for a time period of between approximately 0.1 seconds and approximately 10 seconds, or between approximately 0.5 seconds and approximately 3 seconds, or even between approximately 1 second and 2 seconds.

Upon completion of the purge of the second vapor phase reactant, i.e., the organic precursor (and any reaction byproducts) from the reaction chamber, the cyclic deposition phase 640 may continue by means of a decision gate 630, wherein the decision gate 630 is dependent on the thickness of the UV radiation responsive hybrid material film deposited. For example, if the UV radiation responsive hybrid material film is deposited at an insufficient thickness for a desired application, then the cyclical deposition phase 640 may be repeated by returning to the sub-process block 610 and continuing through a further deposition cycle, wherein a unit deposition cycle may comprise, contacting the substrate with a first vapor phase reactant, such as, for example, a metal precursor (sub-process block 610), purging the reaction chamber, contacting the substrate with an organic precursor (sub-process block 620), and again purging the reaction chamber. A unit deposition cycle of cyclical deposition phase 640 may be repeated one or more times until a desired thickness of an UV radiation responsive hybrid material film is deposited over the substrate. Once the UV radiation responsive hybrid material film has been deposited to the desired thickness the exemplary deposition process 510 may exit via a process block 650 and the substrate, with the UV radiation responsive hybrid material film thereon, may be subjected to further processing for the formation of a hybrid material hard mask material.

It should be appreciated that in some embodiments of the disclosure, the order of contacting of the substrate with the first vapor phase reactant (e.g., the metal precursor) and the second vapor phase reactant (e.g., the organic precursor) may be such that the substrate is first contacted with the second vapor phase reactant followed by the first vapor phase reactant. In addition, in some embodiments, the cyclical deposition phase 640 of exemplary cyclical deposition process 510 may comprise, contacting the substrate with the first vapor phase reactant one or more times prior to contacting the substrate with the second vapor phase reactant one or more times. In addition, in some embodiments, the cyclical deposition phase 640 of exemplary cyclical deposition process 510 may comprise, contacting the substrate with the second vapor phase reactant one or more times prior to contacting the substrate with the first vapor phase reactant one or more times.

The exemplary cyclical deposition process 510 may further comprise an addition sub-process comprising, contacting the substrate with one or more dopant precursors. The process of contacting the substrate with one or more dopants and the details of specific dopant species have been described with reference to cyclical deposition process 110A of FIG. 2 are therefore not repeated in relation to cyclical deposition process 510.

In some embodiments, the UV responsive hybrid material is deposited to have a desired atomic percentage (atomic-%) of carbon. For example, the UV responsive hybrid material may have a carbon concentrations greater than 1 atomic-%, or greater than 5 atomic-%, or greater than 10 atomic-%, or greater than 20 atomic-%, or greater than 30 atomic-%, or even greater than 40 atomic-%. In addition, in some embodiments, the UV responsive hybrid material may have a hydrogen concentration greater than 1 atomic-%, or greater than 5 atomic-%, or greater than 10 atomic-%, or greater than 20 atomic-%, or greater than 30 atomic-%, or even greater than 40 atomic

In some embodiments, the UV responsive hybrid material may be substantially free of tin (Sn). For example, the UV responsive hybrid material may have a tin concentration of less than 20 atomic-%, or less than 10 atomic-%, or less than 5 atomic-%, or less than 1 atomic-%, or less than 0.5 atomic-%, or less than 0.1 atomic-%, or even less than 0.001 atomic-%.

Upon depositing the UV radiation responsive hybrid material film the exemplary process 500 of FIG. 5 may continue by means of a process block 520 comprising, irradiating select portions of the UV responsive hybrid material film with UV radiation.

In more detail, the substrate with UV radiation responsive hybrid material film may be disposed in an UV patterning tool and select portion of the UV radiation responsive hybrid material film may be irradiate with UV thereby forming a hybrid material film with irradiated portions having a first etch rate and non-irradiated portions having a second etch rate different from the first etch rate. In some embodiments, the UV irradiated portions have a first etch rate which is less than the second etch rate of the non-irradiated portions. In some embodiments, the UV irradiated portions have a first etch rate which is greater than the second etch rate of the non-irradiated portions.

In some embodiments, irradiating select portions of the UV responsive hybrid material film to UV radiation further comprises at least partially crystallizing the UV irradiated portions. In some embodiments, irradiating select portions of the UV responsive hybrid material film to UV radiation further comprises increasing the crystallinity of the UV responsive hybrid material. In some embodiments, irradiating select portions of the UV responsive hybrid material film to UV radiation further comprises increasing the etch resistance or structural rigidity of the UV responsive hybrid material.

For example, in some embodiments the UV responsive hybrid material film may be deposited as an amorphous film and irradiating select portions of the UV response hybrid material film may stimulate crystallization of the UV responsive hybrid material film.

Once the UV responsive hybrid material film has been irradiated in select regions to UV radiation the exemplary method 500 of FIG. 5 may continue by means of a process block 530 comprising, directly forming a patterned hybrid material hard mask. For example, the methods of the disclosure may further comprise directly forming a patterned hybrid material hard mask by developing the UV responsive hybrid material film to remove one of the irradiated portions or the non-irradiated portions. In some embodiments, the developing process for removing select portions of the UV responsive hybrid material film may comprise an etch process, such as, for example, one or more of a wet etch process, a dry etch process, or a thermal etch process. As a non-limiting example, the irradiated portions may have first etch rate which may be less than a second etch rate of the non-irradiated portions and therefore during exposure to an etching process the non-irradiated portions will be removed at a higher rate than the irradiated portions allowing for the complete removal of the non-irradiated portions whilst maintaining at least a portion of the irradiation portions. In some embodiments, the wet etch processes and/or the dry etch processes utilized to develop the UV responsive hybrid material may be substantially similar to those described previously in relation to the development of the UV responsive metal oxide-containing film and are therefore not repeated herein. In some embodiments, the UV responsive hybrid material may be etched in a pattern development process utilizing an ashing process comprising exposure of the UV responsive hybrid material to an oxygen-based plasma. In some embodiments, the patterned hybrid material hard mask may comprise an at least partially crystalline film.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for forming an ultraviolet (UV) radiation responsive metal oxide-containing film, the method comprising:
depositing a UV radiation responsive metal oxide-containing film over a substrate, the UV radiation responsive metal oxide-containing film having a substantially uniform etch rate, wherein depositing comprises:
heating the substrate to a deposition temperature of less than 400° C.;
contacting the substrate with a first vapor phase reactant comprising a metal component, a hydrogen component, and a carbon component;
contacting the substrate with a second vapor phase reactant comprising an oxygen-containing precursor; and
contacting the substrate with one or more dopant precursors differing from the first vapor phase reactant to increase a UV responsivity of the UV radiation responsive metal oxide-containing film.

2. The method of claim 1, wherein the first vapor phase reactant comprises a metalorganic precursor.

3. The method of claim 2, wherein the metalorganic precursor comprises triethylaluminum (TEA) or diethylzinc.

4. The method of claim 1, wherein the step of heating comprises heating the substrate to a deposition temperature of less than 200° C.

5. The method of claim 1, wherein the one or more dopant precursors comprise at least one of a metal oxide dopant, a metal dopant, or an alkyl silicon compound dopant.

6. The method of claim 5, wherein the metal dopant is selected from the group comprising: aluminum (Al), zinc (Zn), indium (In), antimony (Sb), or bismuth (Bi).

7. The method of claim 5, wherein the alkyl silicon compound dopant comprises an aminosilane.

8. The method of claim 1, wherein the one or more dopant precursors comprises the metal oxide dopant.

9. The method of claim 1, further comprising:
using a UV patterning tool, selectively UV irradiating the UV radiation-responsive metal oxide-containing film to provide irradiated regions and non-irradiated regions,
wherein the irradiated regions have a first etch rate and the non-irradiated regions have a second etch rate differing from the first etch rate.

10. A structure comprising:
the substrate; and
the ultraviolet (UV) radiation responsive metal oxide-containing film formed according to claim 1.

11. The structure of claim 10, wherein the ultraviolet (UV) radiation responsive metal oxide-containing film comprises a metal oxide dopant selected from at least one of an aluminum oxide, a zinc oxide, an indium oxide, a bismuth oxide, an antimony oxide, a silicon oxide, or a germanium oxide.

12. The structure of claim 10, wherein the ultraviolet (UV) radiation responsive metal oxide-containing film comprises a metal dopant selected from at least one of aluminum, zinc, indium, bismuth, antimony, silicon, tin, or germanium.

13. The structure of claim 10, wherein the ultraviolet (UV) radiation responsive metal oxide-containing film comprises silicon.

14. A method including forming and irradiating an ultraviolet (UV) radiation responsive metal containing film, the method comprising:
depositing an UV radiation responsive metal containing film over a substrate, the UV radiation responsive metal containing film having a substantially uniform etch rate, wherein depositing comprises:
heating the substrate to a deposition temperature of less than 200° C.;
contacting the substrate with a first vapor phase reactant comprising a metal component, a hydrogen component, and a carbon component; and
contacting the substrate with a second vapor phase reactant organic precursor,
wherein the UV radiation responsive metal containing film comprises a hybrid material including an organic component and an inorganic component.

15. The method of claim 14, further comprising contacting the substrate with one or more dopant precursors.

16. The method of claim 15, wherein the one or more dopant precursors comprise at least one of a metal oxide dopant, a metal dopant, or an alkyl silicon compound dopant.

17. The method of claim 16, wherein the metal dopant is selected from the group comprising: aluminum (Al), zinc (Zn), indium (In), antimony (Sb), or bismuth (Bi).

18. The method of claim 14, wherein the hybrid material comprises an inorganic/organic nanolaminate.

19. The method of claim 14, wherein the step of depositing comprises a cyclic deposition process.

20. The method of claim 14, wherein the first vapor phase reactant comprises a metalorganic precursor.
